(19) United States
(12) Patent Application Publication
(10) Pub. No.: US 2024/0322685 A1
(43) Pub. Date: Sep. 26, 2024

(54) POWER SUPPLY CIRCUIT WITH MULTIPLE MODES

(71) Applicant: QUALCOMM Incorporated, San Diego, CA (US)

(72) Inventors: Subbarao Surendra CHAKKIRALA, San Jose, CA (US); Dongyang TANG, San Diego, CA (US)

(21) Appl. No.: 18/189,120

(22) Filed: Mar. 23, 2023

(51) Int. Cl. H02M 3/158; H04R 3/00

(52) U.S. Cl. CPC H02M 3/158; H04R 3/00

(57) ABSTRACT

Certain aspects of the present disclosure generally relate to electronic circuits and, more particularly, to power supply circuit. The power supply circuit may include at least one voltage supply selectively coupled to an output node of the power supply circuit, and a boost converter having: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.

### TECHNICAL FIELD

Certain aspects of the present disclosure generally relate to electronic circuits and, more particularly, to a power supply circuit.

### BACKGROUND

A speaker is a transducer that produces a pressure wave in response to an input electrical signal, and thus, sound is generated. The speaker input signal may be produced by an audio amplifier (also referred to as a “power amplifier”) that receives a relatively lower voltage analog audio signal and generates an amplified signal (with a relatively higher voltage) to drive the speaker. A dynamic loudspeaker is typically composed of a lightweight diaphragm (a cone) connected to a rigid basket (a frame) via a flexible suspension (often referred to as a spider) that constrains a voice coil to move axially through a cylindrical magnetic gap. When the input electrical signal is applied to the voice coil, a magnetic field is created by the electric current in the coil, thereby forming a linear electric motor. By varying the electrical signal from the audio amplifier, the mechanical force generated by the interaction between the magnet and the voice coil is modulated and causes the cone to move back and forth, thereby creating the pressure waves interpreted as sound.

### SUMMARY

The systems, methods, and devices of the disclosure each have several aspects, no single one of which is solely responsible for its desirable attributes. Without limiting the scope of this disclosure as expressed by the claims that follow, some features will now be discussed briefly. After considering this discussion, and particularly after reading the section entitled “Detailed Description,” one will understand how the features of this disclosure provide the advantages described herein.

Certain aspects of the present disclosure generally relate to a power supply circuit. The power supply circuit generally includes at least one voltage supply selectively coupled to an output node of the power supply circuit and a boost converter having: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.

Certain aspects of the present disclosure relate to a power supply circuit. The power supply circuit generally includes at least one voltage supply and a boost converter having an input coupled to a power source and an output selectively coupled to the at least one voltage supply, wherein the at least one voltage supply is configured to provide at least one voltage that is lower than a battery voltage of a cell in the power source.

Certain aspects of the present disclosure generally relate to a method for supply voltage generation. The method generally includes: generating, via a first voltage supply, a first supply voltage; providing the first supply voltage to an output node of the power supply circuit based on an active load having a first output power, the output node being coupled to the active load; and providing, via a boost converter, a second supply voltage to the output node based on the active load having a second output power greater than the first output power. The boost converter may include: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.

Certain aspects of the present disclosure generally relate to an apparatus for supply voltage generation. The apparatus generally includes means for generating a first supply voltage, and means for providing the first supply voltage to an output node of the power supply circuit based on an active load having a first output power, the output node being coupled to the active load. The apparatus may also include a boost converter configured to provide a second supply voltage to the output node based on the active load having a second output power greater than the first output power, the boost converter having: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 illustrates an example audio system, in which aspects of the present disclosure may be practiced.

FIG. 2 illustrates an example power supply circuit, according to certain aspects of the present disclosure.

FIG. 3 is a graph illustrating an output voltage at a power supply output node with different power supply modes based on an amplifier output power, in accordance with certain aspects of the present disclosure.

FIG. 4 is a flow diagram of example operations for supply voltage generation, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure are directed towards a power supply circuit. The power supply circuit may include a plurality of voltage supplies, including a boost converter that facilitates the selective coupling of the boost converter or one or more additional voltage supplies to an output node of the power supply circuit. For example, the boost converter or one of the additional voltage supplies may be selectively coupled to the output node based on an amount of power draw from a load (e.g., an amplifier). The boost converter may generate a boosted voltage based on a power source (e.g., a battery). At least one of the additional voltage supplies may output a lower voltage than a voltage of the power source, in an effort to increase low power efficiency of the power supply circuit. In some cases, the boost converter may be configured in a bypass mode, electrically coupling the power source to the output node of the power supply circuit, as described in more detail herein.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Example Audio System with a Power Amplifier

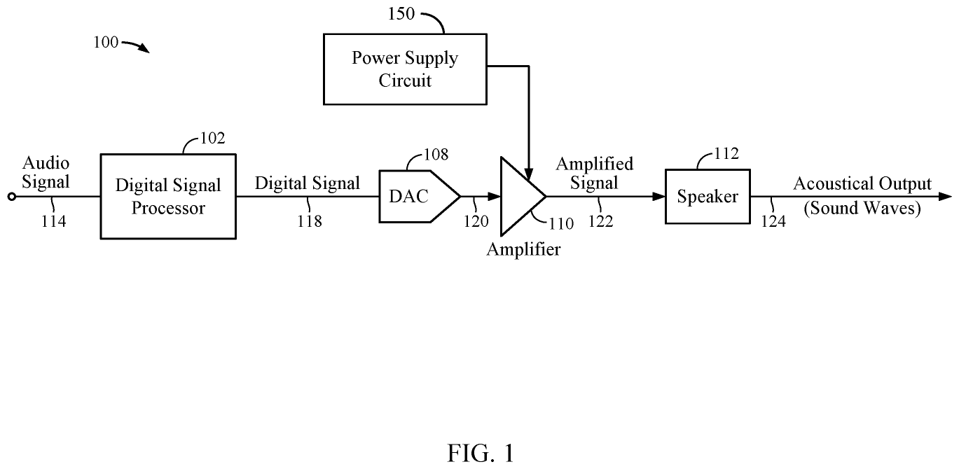

FIG. 1 illustrates an example audio system 100, in which aspects of the present disclosure may be practiced. However, it is to be understood that aspects of the present disclosure may also be practiced in any of various other suitable amplification scenarios.

As illustrated in FIG. 1, a digital signal processor (DSP) 102 may receive and process audio signals 114 (e.g., a digital audio signal) by, for example, applying a digital filter aimed at increasing audio quality. The filtered or otherwise processed digital signal 118 produced by the DSP 102 (or a further processed version thereof) may be converted to an analog signal 120 using a digital-to-analog converter (DAC) 108. In certain aspects, the DAC may be implemented as part of the DSP 102 or an amplifier 110. In certain aspects, the analog signal 120 may be amplified using the amplifier 110 to generate an amplified signal 122. The amplified signal 122 may drive a speaker 112 to produce an acoustic output 124 (e.g., sound waves). In other words, the amplifier 110 may function as a speaker driver. In some aspects, the audio system 100 may include a power supply system 150. The power supply system 150 may generate a supply voltage for the amplifier 110.

Some speaker amplifiers may have degraded efficiency when operating at low power. For example, at low power, the amplifier's efficiency may be limited by the quiescent current of the amplifier and the switching losses in a power supply stage (e.g., power supply system 150) used to power the amplifier. For a single-stacked (1S) battery, the quiescent current as well as the switching current of the switching power supply loop may be supplied from the single-cell battery (e.g., a battery providing a 4.2V supply). For dual-stacked (2S) or triple-stacked (3S) batteries, the quiescent current and switching current may be supplied from the 2S battery (e.g., providing an 8.4 V supply) or the 3S battery (e.g., providing a 12.6V supply). In other words, the amplifier may have low efficiency when outputting low voltages (e.g., lower than the voltage of the battery, especially when power is supplied from a 2S or 3S battery).

In some aspects of the present disclosure, different voltage supplies may be used depending on a power draw associated with the amplifier. When using a 1S battery, the amplifier power may be supplied with a lower voltage (e.g., 1.8 V), so long as the lower voltage can support the power draw of the amplifier. As the power draw of the amplifier increases, the 1S battery supply may be used (e.g., in a bypass mode of the boost converter) to supply the power to the amplifier.

When using a 2S or 3S battery, the amplifier power may be supplied with a lower voltage (e.g., 1.8 V and/or 3.3 V) from a first power supply, so long as the lower voltage can support the amplifier power draw. As the power draw of the amplifier increases, a second power supply (e.g., providing 3.3 V) or the 1S battery (e.g., providing a 4.2 V supply) may be used, followed by power from the 2S or 3S battery (e.g., providing an 8.4 V supply or a 12.6 V supply, respectively). As the power draw of the amplifier further increases, a boosted voltage may be generated using a switching power supply and provided to the amplifier.

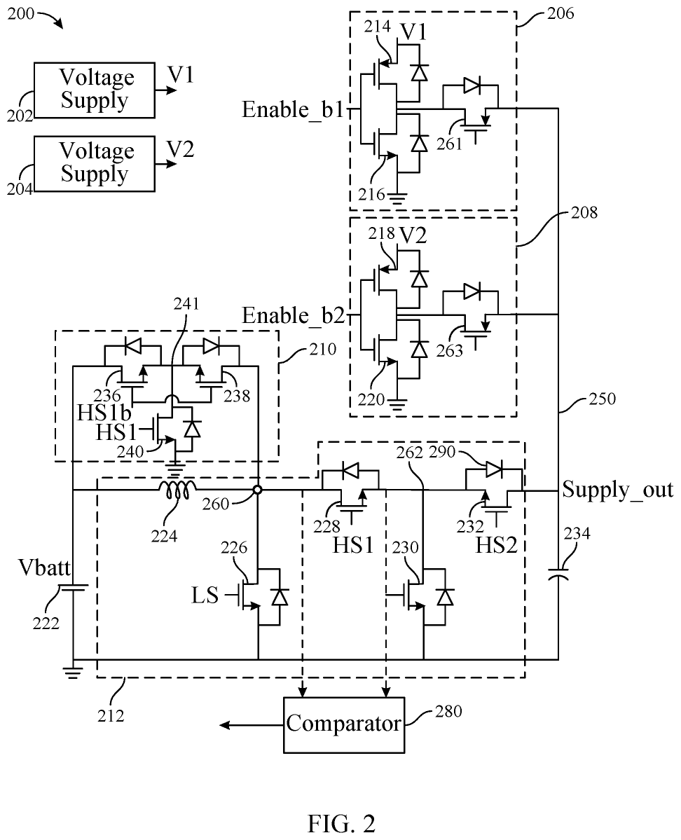

FIG. 2 illustrates an example power supply circuit 200 (e.g., corresponding to power supply system 150 of FIG. 1), in accordance with certain aspects of the present disclosure. As shown, the power supply circuit 200 may include a voltage supply 202 providing a first voltage (V1) and a voltage supply 204 providing a second voltage (V2). In some aspects, the voltage supplies 202, 204 may generate supply voltages based on a voltage from a power source (e.g., a battery such as battery 222, which may be a stacked multi-cell battery in some cases).

As shown, the output of the voltage supply 202 may be selectively coupled to an output node 250 of the power supply circuit 200 via enable circuitry 206. The output node 250 may be coupled to an output capacitive element 234, as shown. The enable circuitry 206 may include a p-channel metal-oxide-semiconductor (PMOS) transistor 214 having a source coupled to the output of the voltage supply 202 and an n-channel metal-oxide-semiconductor (NMOS) transistor 216 having a source coupled to a reference potential node (e.g., electrical ground). The gates of transistors 214, 216 may be driven by a complementary enable signal (Enable_b 1), as shown. The drains of the transistors 214, 216 may be coupled together and may be selectively coupled to the output node 250 through a transistor 261 (e.g., a PMOS transistor). When the complementary enable signal provided to the gates of transistors 214, 216 is logic low, the transistor 214 is turned on, and the transistor 216 is turned off. Moreover, the gate of transistor 261 may be driven by a logic low signal. Thus, the transistor 261 may be turned on, providing the voltage V1 to the output node 250.

Similarly, the output of the voltage supply 204 may be selectively coupled to the output node 250 via enable circuitry 208. The enable circuitry 208 may include a PMOS transistor 218 having a source coupled to the output of the voltage supply 204 and an NMOS transistor 220 having a source coupled to the reference potential node (e.g., electrical ground). The gates of transistors 218, 220 may be driven by a complementary enable signal (e.g., Enable_b 2), as shown. The drains of the transistors 218, 220 may be coupled together and may be selectively coupled to the output node 250 through a transistor 263 (e.g., a PMOS transistor). When the complementary enable signal provided to the gates of transistors 218, 220 is logic low, the transistor 218 is turned on, and the transistor 220 is turned off. Moreover, the gate of transistor 263 may be driven by a logic low signal. Thus, the transistor 263 may be turned on, providing the voltage V2 to the output node 250.

The power supply circuit 200 may also include a boost converter 212 configured to generate, at the output node 250, a boosted voltage based on a battery voltage (Vbatt) from a battery 222. The boost converter 212 may be operable in a bypass mode or a boost mode. In the example of FIG. 2, the boost converter 212 may include an inductive element 224 coupled between a voltage source (e.g., battery 222) and a switching node 260. A low-side (LS) transistor 226 (e.g., switch) may be coupled between the switching node 260 and the reference potential node (e.g., electrical ground). A first high-side (HS) transistor 228 (e.g., switch) may be coupled between the switching node 260 and node 262. A second HS transistor 232 (e.g., switch) may be coupled between node 262 and the output node 250. A shunt transistor 230 (e.g., switch) may be coupled between node 262 and the reference potential node, as shown.

The transistor 228 allows the voltage at the output node 250 to be set to a voltage lower than Vbatt (e.g., allowing the voltage at the output node 250 to be V1). In other words, without transistor 228 (e.g., if the source of transistor 232 was directly coupled to inductive element 224), the voltage at the output node 250 could not be set below Vbatt minus Vdiode (where Vdiode is the forward voltage of the body diode 290 of transistor 232), without drawing power from the battery 222.

In bypass mode, transistors 228, 232 may be turned on (and transistors 226, 230 may be turned off), electrically coupling the battery 222 to the output node 250 (e.g., effectively bypassing the boost operations). In boost mode, transistor 228 may be turned on, transistor 230 may be turned off, and transistors 226, 232 may be controlled (e.g., pulse-width modulated) to perform boost operations for generating a boosted voltage at the output node 250.

As described herein, the battery 222 may be implemented as a 1S battery or a multi-cell battery (e.g., a 2S battery or a 3S battery). With a 1S battery, an active load (e.g., the amplifier 110 described with respect to FIG. 1) may be supplied with a lower voltage (e.g., V1=1.8 V generated via voltage supply 202). For example, the output of the voltage supply 202 may be electrically coupled to the output node 250 via the enable circuitry 206. The boost converter 212 may be turned off while the output of the voltage supply 202 is electrically coupled to the output node 250 (e.g., by turning off transistors 228, 232).

As the power draw from the active load increases, the voltage from the 1S battery may be used to power the active load. For example, the boost converter 212 may be configured in bypass mode, electrically coupling the battery 222 to the output node 250 (e.g., through inductive element 224 and turned-on transistors 228, 232). As the active load power draw increases (e.g., above the 1S battery voltage, minus some headroom voltage), the boost converter 212 may be configured to generate a boosted voltage at the output node 250 to be provided to the active load.

With a 2S or 3S battery, the active load may be supplied with a lower voltage (e.g., V1=1.8 V generated via voltage supply 202). As the active load power draw increases, the active load may be supplied with a higher voltage (e.g., V2=3.3 V or 4.2 V generated via voltage supply 204 or 4.2 V from a single cell of the 2S or 3S battery). As the active load power draw increases further, the boost converter 212 may be configured in bypass mode, providing the voltage from the 2S or 3S battery to the output node 250, followed by the boost converter 212 generating a boosted voltage at the output node 250.

While transitions between voltage supplies are described as the power draw from the active load (e.g., amplifier 110) increases, similar transitions may occur as the power draw from the active load decreases. For example, as the power draw from the active load decreases, the boost converter 212 may transition from boost mode to bypass mode. As the power draw of the active load further decreases, the voltage supply 204 may be used to provide V2 to the active load, followed by voltage supply 202 being used to provide V1 to the active load.

While transitioning from high load power to low load power (e.g., from bypass mode to providing V2 from voltage supply 204 or providing V1 from voltage supply 202), a current path (e.g., discharge path) may be provided for inductive element 224. In other words, while providing current to the output node 250, the inductive element 224 charges. Without a discharge path when the current path from the inductive element 224 to the output node 250 is opened (e.g., by turning off transistor 228), a voltage spike may occur at the switching node 260, degrading supply performance and reliability. In some aspects, a discharge path may be provided for the inductive element 224. For example, a discharge circuit 210 (e.g., providing a diode current freewheeling path) may be coupled in parallel with inductive element 224. The discharge circuit 210 may include an NMOS transistor 236 having a drain coupled to a first terminal of the inductive element 224 and an NMOS transistor 238 having a drain coupled to a second terminal of the inductive element 224. An NMOS transistor 240 may be coupled between the sources of transistors 236, 238 and a reference potential node (e.g., electrical ground). As shown, the gates of transistors 236, 238 may be controlled via an HS1b signal which is an inverse of an HS1 signal used to drive the gate of transistor 228. Moreover, the gate of transistor 240 may be controlled via the HS1 signal. For example, when the transistor 228 is turned off (e.g., electrically decoupling the inductive element 224 from output node 250), the inductor current may be discharged via the discharge circuit 210 by turning on transistors 236, 238 and turning off transistor 240. When the transistor 228 is turned on, the transistor 240 may be turned on and the transistors 236, 238 may be turned off, coupling the node 241 to the reference potential node (e.g., electrical ground).

In some aspects, instead of using discharge circuit 210 (or in addition to using discharge circuit 210), the transition to using voltage supplies 202, 204 may occur when the current in inductive element 224 is (or is close to) zero. For example, a comparator 280 may be used to sense and compare the drain and source voltages of transistor 228. When the drain and source voltages are equal (or about equal), indicating zero current across inductive element 224, the voltage supply transition may occur by turning off transistor 228. In some aspects, when the boost converter is effectively turned off (e.g., both transistors 228, 232 are turned off), the transistor 230 may be turned on to couple the node 262 to the reference potential node (e.g., couple node 262 to electrical ground so that node 262 is not floating). Transistors 228, 232 may be referred to as back-to-back transistors because the source of transistor 228 is coupled to the source of transistor 232, resulting in the body diodes of the transistors 228, 232 being back-to-back (e.g., anode coupled to anode).

While two additional voltage supplies 202, 204 are depicted in FIG. 2, it is to be understood that the power supply circuit may include one additional voltage supply or more than two additional voltage supplies, which may be selectively coupled to the output node 250. At least one of the additional voltage supplies may provide a voltage that is lower than the 1S battery voltage. The additional voltage supplies may be coupled to the output node 250 via enable circuitry, which may be similar to the enable circuitry 206, 208 described above.

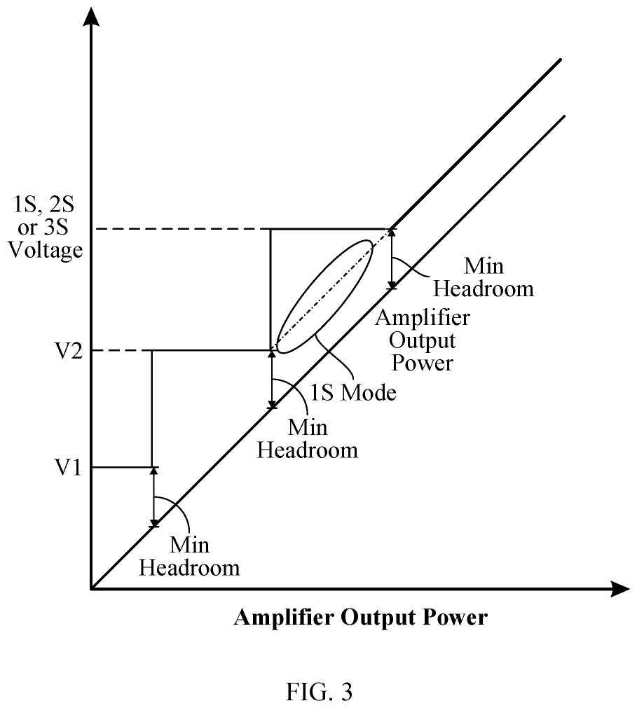

FIG. 3 is a graph illustrating an output voltage at the output node 250 with respect to amplifier output voltage (and power), in accordance with certain aspects of the present disclosure. As shown, as amplifier output voltage (e.g., corresponding to amplifier power draw from the power supply circuit 200) increases from zero volts, the output voltage transitions from V1 to V2, then from V2 to Vbatt (e.g., 1S, 2S, 3S stacked battery voltage), then to a boosted voltage that corresponds to the amplifier output power (e.g., increases along with the amplifier output power), keeping some minimum headroom voltage above the amplifier output voltage, as shown. Similar transitions may occur as the amplifier output power decreases, as described herein.

Certain aspects of the present disclosure provide a power supply circuit able to achieve significantly increased efficiency at low operating power and for various stacked-battery modes, compared to at least some conventional implementations. For example, the power supply circuit may achieve greater than 20% efficiency improvement in 2S mode at low power and greater than 30% efficiency improvement in 3S mode at low power, as compared to some conventional implementations.

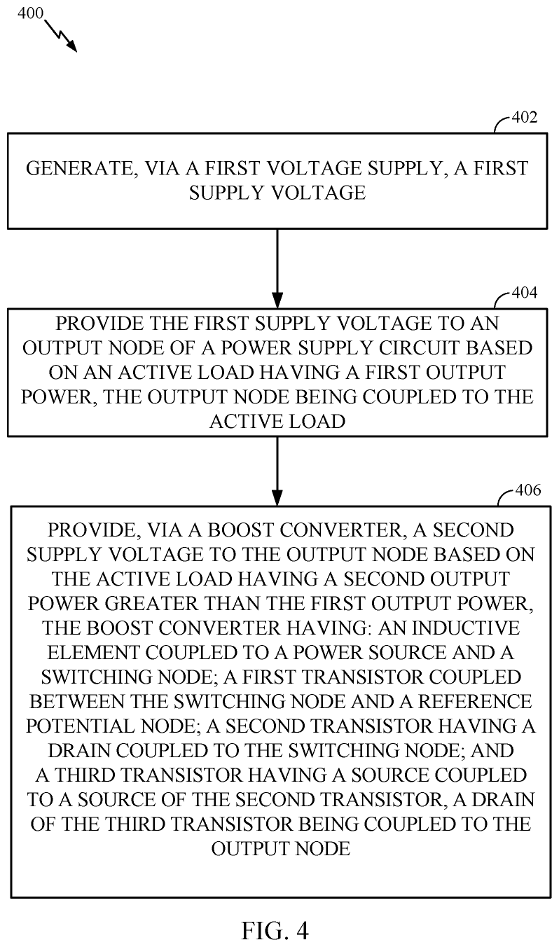

FIG. 4 is a flow diagram of example operations 400 for supply voltage generation, in accordance with certain aspects of the present disclosure. The operations 400 may be performed by a power supply circuit, such as the power supply circuit 200.

The operations 400 may begin, at block 402, with the power supply circuit generating, via a first voltage supply (e.g., voltage supply 202), a first supply voltage. At block 404, the power supply circuit provides the first supply voltage to an output node (e.g., output node 250) of the power supply circuit based on an active load (e.g., an amplifier, such as amplifier 110) having a first output power. The output node may be coupled to a power supply input of the active load.

At block 406, the power supply circuit provides, via a boost converter (e.g., boost converter 212), a second supply voltage to the output node based on the active load having a second output power greater than the first output power. The boost converter may include an inductive element (e.g., inductive element 224) coupled to a power source (e.g., battery 222) and a switching node (e.g., switching node 260). The boost converter may also include a first transistor (e.g., transistor 226) coupled between the switching node and a reference potential node (e.g., electrical ground), a second transistor (e.g., transistor 228) having a drain coupled to the switching node, and a third transistor (e.g., transistor 232) having a source coupled to a source of the second transistor, a drain of the third transistor being coupled to the output node.

In some aspects, providing the first supply voltage to the output node may include coupling the first voltage supply to the output node via first enable circuitry (e.g., enable circuitry 206). The enable circuitry may include a fourth transistor (e.g., transistor 214) having a source coupled to the first voltage supply, a fifth transistor (e.g., transistor 216) having a source coupled to a reference potential node (e.g., electrical ground), a sixth transistor (e.g., transistor 261) having a drain coupled to drains of the fourth transistor and the fifth transistor and a source coupled to the output node. In some aspects, the power supply circuit selectively couples a second voltage supply to the output node based on the active load having a third output power. The third output power may be greater than the first output power and less than the second output power.

In some aspects, the power supply circuit provides a discharge path for the inductive element via a discharge circuit (e.g., discharge circuit 210) coupled in parallel with the inductive element. The discharge path may be provided for the inductive element based on the second transistor being turned off. In some aspects, the power supply circuit configures the boost converter in a bypass mode by turning on the second transistor and the third transistor.

In some aspects, the power supply circuit senses, via a sense circuit (e.g., comparator 280), a current across the inductive element and turns off the second transistor based on the current. Sensing the current across the inductive element may include comparing a source voltage and a drain voltage of the second transistor via a comparator. In some aspects, the power supply circuit may turn on a fourth transistor (e.g., transistor 230) coupled between the reference potential node and sources of the second transistor and the third transistor based on the second transistor and the third transistor being turned off.

### Example Aspects

In addition to the various aspects described above, specific combinations of aspects are within the scope of the disclosure, some of which are detailed below:
Aspect 1. A power supply circuit, comprising: at least one voltage supply selectively coupled to an output node of the power supply circuit; and a boost converter having: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.
Aspect 2. The power supply circuit of aspect 1, wherein the power source comprises a single-cell battery and wherein the at least one voltage supply is configured to have at least one lower voltage than a battery voltage of the single-cell battery.
Aspect 3. The power supply circuit of aspect 1 or 2, wherein the power source comprises a stacked multi-cell battery and wherein the at least one voltage supply is configured to have at least one lower voltage than a battery voltage of a cell in the stacked multi-cell battery.
Aspect 4. The power supply circuit of any of aspects 1-3, wherein the at least one voltage supply includes a first voltage supply selectively coupled to the output node via first enable circuitry.
Aspect 5. The power supply circuit of aspect 4, wherein the first enable circuitry includes: a fourth transistor having a source coupled to the first voltage supply; a fifth transistor having a source coupled to the reference potential node; and a sixth transistor having a drain coupled to drains of the fourth transistor and the fifth transistor and a source coupled to the output node.
Aspect 6. The power supply circuit of aspect 4 or 5, wherein the at least one voltage supply further includes a second voltage supply selectively coupled to the output node via second enable circuitry.
Aspect 7. The power supply circuit of any of aspects 1-6, further comprising a discharge circuit coupled in parallel with the inductive element.
Aspect 8. The power supply circuit of aspect 7, wherein the discharge circuit comprises: a fourth transistor having a drain coupled to the power source; a fifth transistor having a drain coupled to the switching node; and a sixth transistor having a drain coupled to sources of the fourth transistor and the fifth transistor, wherein a source of the sixth transistor is coupled to the reference potential node.
Aspect 9. The power supply circuit of aspect 7 or 8, wherein the discharge circuit is configured to provide a discharge path for the inductive element based on the second transistor being turned off.
Aspect 10. The power supply circuit of any of aspects 7-9, wherein the boost converter is configured in a bypass mode by turning on the second transistor and the third transistor and by turning off the first transistor.
Aspect 11. The power supply circuit of any of aspects 1-10, further comprising a sense circuit configured to sense a current across the inductive element, wherein the second transistor is configured to be turned off based on the current.
Aspect 12. The power supply circuit of aspect 11, wherein the sense circuit comprises a comparator configured to sense the current across the inductive element by comparing a source voltage and a drain voltage of the second transistor.
Aspect 13. The power supply circuit of any of aspects 1-12, wherein: the output node is for coupling to an active load; the at least one voltage supply is coupled to the output node and the boost converter is decoupled from the output node, based on the active load being configured to have a first output power; the boost converter is configured in a bypass mode and the at least one voltage supply is decoupled from the output node, based on the active load being configured to have a second output power greater than the first output power; and the boost converter is configured in a boost mode and the at least one voltage supply is decoupled from the output node, based on the active load being configured to have a third output power greater than the second output power.
Aspect 14. The power supply circuit of aspect 13, wherein the boost converter is configured in the bypass mode by turning on the second transistor and the third transistor.
Aspect 15. The power supply circuit of any of aspects 1-14, further comprising a fourth transistor coupled between the reference potential node and sources of the second transistor and the third transistor.
Aspect 16. A power supply circuit, comprising: at least one voltage supply; and a boost converter having an input coupled to a power source and an output selectively coupled to the at least one voltage supply, wherein the at least one voltage supply is configured to provide at least one voltage that is lower than a battery voltage of a cell in the power source.
Aspect 17. The power supply circuit of aspect 16, wherein the boost converter comprises: an inductive element coupled between the power source and a switching node; a first switch coupled between the switching node and a reference potential node of the power supply circuit; and a second switch coupled to the output of the boost converter and selectively coupled to the switching node.
Aspect 18. The power supply circuit of aspect 17, wherein the boost converter further comprises a third switch coupled between the second switch and the switching node.
Aspect 19. The power supply circuit of aspect 18, wherein the second switch and the third switch comprise back-to-back transistors.
Aspect 20. A method for supply voltage generation, comprising: generating, via a first voltage supply, a first supply voltage; providing the first supply voltage to an output node of a power supply circuit based on an active load having a first output power, the output node being coupled to the active load; and providing, via a boost converter, a second supply voltage to the output node based on the active load having a second output power greater than the first output power, the boost converter having: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.
Aspect 21. The method of aspect 20, wherein providing the first supply voltage to the output node includes coupling the first voltage supply to the output node via enable circuitry.
Aspect 22. The method of aspect 21, wherein the enable circuitry includes: a fourth transistor having a source coupled to the first voltage supply; a fifth transistor having a source coupled to the reference potential node; and a sixth transistor having a drain coupled to drains of the fourth transistor and the fifth transistor and a source coupled to the output node.
Aspect 23. The method of aspect 21 or 22, further comprising selectively coupling a second voltage supply to the output node based on the active load having a third output power, the third output power being greater than the first output power and less than the second output power.
Aspect 24. The method of any of aspects 20-23, further comprising providing a discharge path for the inductive element via a discharge circuit coupled in parallel with the inductive element.
Aspect 25. The method of aspect 24, wherein the discharge path is provided for the inductive element based on the second transistor being turned off.
Aspect 26. The method of aspect 24 or 25, further comprising configuration the boost converter in a bypass mode by turning on the second transistor and the third transistor.
Aspect 27. The method of any of aspects 20-26, further comprising: sensing, via a sense circuit, a current across the inductive element; and turning off the second transistor based on the current.
Aspect 28. The method of aspect 27, wherein sensing the current across the inductive element includes comparing a source voltage and a drain voltage of the second transistor via a comparator.
Aspect 29. The method of any of aspects 20-28, further comprising turning on a fourth transistor coupled between the reference potential node and sources of the second transistor and the third transistor based on the second transistor and the third transistor being turned off.
Aspect 30. An apparatus for supply voltage generation, comprising: means for generating a first supply voltage; means for providing the first supply voltage to an output node of a power supply circuit based on an active load having a first output power, the output node being coupled to the active load; and a boost converter configured to provide a second supply voltage to the output node based on the active load having a second output power greater than the first output power, the boost converter having: an inductive element coupled to a power source and a switching node; a first transistor coupled between the switching node and a reference potential node; a second transistor having a drain coupled to the switching node; and a third transistor having a source coupled to a source of the second transistor, a drain of the third transistor being coupled to the output node.

### ADDITIONAL CONSIDERATIONS

The various operations of methods described above may be performed by any suitable means capable of performing the corresponding functions. The means may include various hardware and/or software component(s) and/or module(s), including, but not limited to a circuit, an application-specific integrated circuit (ASIC), or processor. Generally, where there are operations illustrated in figures, those operations may have corresponding counterpart means-plus-function components with similar numbering. For example, means for generating may include a voltage supply, such as the voltage supply 202 or voltage supply 204. Means for providing may include enable circuitry, such as enable circuitry 206 or enable circuitry 208.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

It is to be understood that the claims are not limited to the precise configuration and components illustrated above. Various modifications, changes and variations may be made in the arrangement, operation, and details of the methods and apparatus described above without departing from the scope of the claims.

What is claimed is:

1. A power supply circuit, comprising:
at least one voltage supply selectively coupled to an output node of the power supply circuit; and
a boost converter having:
an inductive element coupled to a power source and a switching node;
a first transistor coupled between the switching node and a reference potential node;
a second transistor having a drain coupled to the switching node; and
a third transistor having a source coupled to a source of the second transistor, a drain of the third transistor being coupled to the output node.

2. The power supply circuit of claim 1, wherein the power source comprises a single-cell battery and wherein the at least one voltage supply is configured to have at least one lower voltage than a battery voltage of the single-cell battery.

3. The power supply circuit of claim 1, wherein the power source comprises a stacked multi-cell battery and wherein the at least one voltage supply is configured to have at least one lower voltage than a battery voltage of a cell in the stacked multi-cell battery.

4. The power supply circuit of claim 1, wherein the at least one voltage supply includes a first voltage supply selectively coupled to the output node via first enable circuitry.

5. The power supply circuit of claim 4, wherein the first enable circuitry includes:
a fourth transistor having a source coupled to the first voltage supply;
a fifth transistor having a source coupled to the reference potential node; and
a sixth transistor having a drain coupled to drains of the fourth transistor and the fifth transistor and a source coupled to the output node.

6. The power supply circuit of claim 4, wherein the at least one voltage supply further includes a second voltage supply selectively coupled to the output node via second enable circuitry.

7. The power supply circuit of claim 1, further comprising a discharge circuit coupled in parallel with the inductive element.

8. The power supply circuit of claim 7, wherein the discharge circuit comprises:
a fourth transistor having a drain coupled to the power source;
a fifth transistor having a drain coupled to the switching node; and
a sixth transistor having a drain coupled to sources of the fourth transistor and the fifth transistor, wherein a source of the sixth transistor is coupled to the reference potential node.

9. The power supply circuit of claim 7, wherein the discharge circuit is configured to provide a discharge path for the inductive element based on the second transistor being turned off.

10. The power supply circuit of claim 7, wherein the boost converter is configured in a bypass mode by turning on the second transistor and the third transistor and by turning off the first transistor.

11. The power supply circuit of claim 1, further comprising a sense circuit configured to sense a current across the inductive element, wherein the second transistor is configured to be turned off based on the current.

12. The power supply circuit of claim 11, wherein the sense circuit comprises a comparator configured to sense the current across the inductive element by comparing a source voltage and a drain voltage of the second transistor.

13. The power supply circuit of claim 1, wherein:
the output node is for coupling to an active load;
the at least one voltage supply is coupled to the output node and the boost converter is decoupled from the output node, based on the active load being configured to have a first output power;
the boost converter is configured in a bypass mode and the at least one voltage supply is decoupled from the output node, based on the active load being configured to have a second output power greater than the first output power; and
the boost converter is configured in a boost mode and the at least one voltage supply is decoupled from the output node, based on the active load being configured to have a third output power greater than the second output power.

14. The power supply circuit of claim 13, wherein the boost converter is configured in the bypass mode by turning on the second transistor and the third transistor.

15. The power supply circuit of claim 1, further comprising a fourth transistor coupled between the reference potential node and sources of the second transistor and the third transistor.

16. A power supply circuit, comprising:
at least one voltage supply; and
a boost converter having an input coupled to a power source and an output selectively coupled to the at least one voltage supply, wherein the at least one voltage supply is configured to provide at least one voltage that is lower than a battery voltage of a cell in the power source.

17. The power supply circuit of claim 16, wherein the boost converter comprises:
an inductive element coupled between the power source and a switching node;
a first switch coupled between the switching node and a reference potential node of the power supply circuit; and
a second switch coupled to the output of the boost converter and selectively coupled to the switching node.

18. The power supply circuit of claim 17, wherein the boost converter further comprises a third switch coupled between the second switch and the switching node.

19. The power supply circuit of claim 18, wherein the second switch and the third switch comprise back-to-back transistors.

20. A method for supply voltage generation, comprising:
generating, via a first voltage supply, a first supply voltage;
providing the first supply voltage to an output node of a power supply circuit based on an active load having a first output power, the output node being coupled to the active load; and
providing, via a boost converter, a second supply voltage to the output node based on the active load having a second output power greater than the first output power, the boost converter having:
an inductive element coupled to a power source and a switching node;
a first transistor coupled between the switching node and a reference potential node;
a second transistor having a drain coupled to the switching node; and
a third transistor having a source coupled to a source of the second transistor, a drain of the third transistor being coupled to the output node.

21. The method of claim 20, wherein providing the first supply voltage to the output node includes coupling the first voltage supply to the output node via enable circuitry.

22. The method of claim 21, wherein the enable circuitry includes:
a fourth transistor having a source coupled to the first voltage supply;
a fifth transistor having a source coupled to the reference potential node; and
a sixth transistor having a drain coupled to drains of the fourth transistor and the fifth transistor and a source coupled to the output node.

23. The method of claim 21, further comprising selectively coupling a second voltage supply to the output node based on the active load having a third output power, the third output power being greater than the first output power and less than the second output power.

24. The method of claim 20, further comprising providing a discharge path for the inductive element via a discharge circuit coupled in parallel with the inductive element.

25. The method of claim 24, wherein the discharge path is provided for the inductive element based on the second transistor being turned off.

26. The method of claim 24, further comprising configuration the boost converter in a bypass mode by turning on the second transistor and the third transistor.

27. The method of claim 20, further comprising:
sensing, via a sense circuit, a current across the inductive element; and
turning off the second transistor based on the current.

28. The method of claim 27, wherein sensing the current across the inductive element includes comparing a source voltage and a drain voltage of the second transistor via a comparator.

29. The method of claim 20, further comprising turning on a fourth transistor coupled between the reference potential node and sources of the second transistor and the third transistor based on the second transistor and the third transistor being turned off.

30. An apparatus for supply voltage generation, comprising:
means for generating a first supply voltage;
means for providing the first supply voltage to an output node of a power supply circuit based on an active load having a first output power, the output node being coupled to the active load; and
a boost converter configured to provide a second supply voltage to the output node based on the active load having a second output power greater than the first output power, the boost converter having:
an inductive element coupled to a power source and a switching node;
a first transistor coupled between the switching node and a reference potential node;
a second transistor having a drain coupled to the switching node; and
a third transistor having a source coupled to a source of the second transistor, a drain of the third transistor being coupled to the output node.
